(19) United States
(12) Patent Application Publication
(10) Pub. No.: US 2026/0247906 A1
(43) Pub. Date: Aug. 20, 2026

(54) METHOD AND SYSTEM FOR APPLYING A FLUID DISCHARGED FROM A SLOT-DIE HEAD TO ONE OR MORE ADVANCING SUBSTRATES

(71) Applicant: FOM Technologies A/S, Kastrup (DK)

(72) Inventor: César Omar Ramírez QUIROZ

(73) Assignee: FOM Technologies A/S, Kastrup (DK)

(21) Appl. No.: 19/162,744

(22) PCT Filed: Mar. 14, 2024
(86) PCT No.: PCT/DK2024/050048

§ 371 Date: Sep. 5, 2025

(30) Foreign Application Priority Data
Mar. 17, 2023 (DK) PA202370136

(51) Int. Cl. H10P 72/00; B05C 5/02; H10F 71/00; H10P 72/30; H10P 72/70

(52) U.S. Cl. CPC H10P 72/0448; B05C 5/0254; H10P 72/0436; H10P 72/3314; H10P 72/7402; H10P 72/7412; H10F 71/134

(57) ABSTRACT

There is provided a method and a system for applying a fluid discharged from a slot-die head on the front surface of one or more advancing substrates. The slot-die head holds a discharge slot and a meniscus guide. An adhesive substrate carrier tape having an adhesive front surface holds the one or more substrates on its front surface. The carrier tape holding the one or more substrates is advanced in a machine direction past the discharge slot of the slot-die head while the fluid is discharged from the discharge slot as a wet film layer on the front surface of the one or more substrates. The system holds an alignment support for supporting the back surface of the carrier tape to maintain a predetermined distance between the front surface of the carrier tape and a bottom edge of the meniscus guide.

### TECHNICAL FIELD

The present disclosure relates to a method and system for discharging a fluid from a slot-die head on the front surface of one more advancing substrates. The substrates may be temporarily sealed to a carrier tape or foil while being advanced past the slot-die head. The substrates may be wafer-plates, such as silicon wafers used in photovoltaics.

### BACKGROUND OF THE INVENTION

A fundamental building block of the semiconductor industry is the silicon wafer. A silicon wafer is a thin plate cut from a purified silicon melt monocrystal or ingot. Depending on the application, the thickness, size, and shape vary from a finite number of possibilities according to the current industry standards. In the case of photovoltaics, a solar module typically comprises many electrically connected silicon wafers placed next to each other. The production facilities for wafers, cells, and modules are compatible with specific geometries. Therefore, any change to these facilities outside their expected energy-pay-back time cycle represents additional capital expenditures. A typical size for photovoltaic manufacturing is M6 or 166 millimetres semi-square. However, a likely trend in the industry is for M12 (210 millimetres squared) to replace M6 gradually. For this transition to occur, several intermediate formats play significant roles, some of which differ by only a few millimetres. As opposed to the case of photovoltaics, the number of devices per wafer is increased to a maximum in the field of LEDs, microchips, and other micro-or nano-structured semiconductor devices. Therefore, the wafer is not reshaped. Instead, it keeps its pristine circular shape with an additional flat cut according to its crystallographic planes. The nomenclature of the different sizes is according to their diameter in inches, e.g., 6, 8, and 12 inches.

Typical fabrication protocols in semiconductors include coating a functional layer as a liquid solution across the entire area of the wafer plate. For instance, the multiple photolithographic steps needed for manufacturing microchips rely on applying a photoresist. This photoresist film thickness ranges from 1 micron to a few hundred microns, and the deposition technique predominantly used is spin coating. Spin-coating is a deposition technique where a relatively large volume of the solution is dispensed onto the spinning wafer plate. The spinning velocity of the wafer plate defines the final wet film thickness for a given solution, where the lower limit is rheology dependent. After the volume is dispensed at the beginning or during the motion of the wafer, the centrifugal forces generated by thousands of revolutions per minute create the necessary liquid-vapor interface to reach the final thickness. As centrifugal force is directly proportional to the distance from the origin, spin coating is intrinsically limited in terms of the size of the substrate and operational thickness range. At the end of the spin-coating, a conservative estimation of around 2% of the solution remains in the film. The rest is recirculated or discarded. Considering that some of the more complex microchip designs require the order of 20 or 50 photolithography steps, current coating protocols might be considered somewhat wasteful. Particularly with the expectation that the industry focuses on resource scarcity, waste, and pollution reduction.

Another example of solution-processed coatings on top of wafer plates is silicon-based photovoltaics. Internationally recognized roadmap statements in the industry recently acknowledged using new-generation materials as necessary developments for advancing the field. The so-called new-generation materials consist of a thin film sequence added to the silicon solar cell as a second complementary solar cell forming a tandem. This thin-film-based top-cell absorbs a complementary section of the solar spectrum, thereby increasing the overall sunlight-to-electricity conversion efficiency. One of the more successful new-generation solar cell materials is referred to as perovskites. One of the attributes of perovskites is that they can be dissolved and coated. However, several challenges emerge when considering state-of-the-art deposition methodologies and mainstream fabrication protocols rendering spin-coating an unlikely option.

One technique for manufacturing a homogeneous wet film coating layer from a dissolved material may be “slot-die coating.” This technique comprises a pumping element driving a solution into a slot-die head component. The solution is uniformly distributed across the slot-die component into an internal solution reservoir or manifold. The manifold connects into a narrow cavity through a meniscus guide and shim elements guiding the solution downwards into a target substrate. Continuous downward flow creates a volume accumulation at the bottom end of the slot-die component with a gravitational pull larger than the intermolecular forces keeping the solution together. The collapse of the volume overflow creates contact between the bottom surface of the meniscus guide element and the surface of the target substrate plate. Once the solution bridge or meniscus forms, the excess volume distributes across the extension of the meniscus guide and the extent of the substrate. A combination of a continuous flow feeding the meniscus volume and a moving substrate creates a wet film with a width equal to the width of the shim. The wet film thickness is directly proportional to the pump rate and inversely proportional to the extension of the meniscus and the velocity at which the substrate moves. The direct correlation between the coating parameters and the resulting film makes slot-die coating a pre-metered technique. As opposed to spin-coating, with slot-die coating, all the solution leaving the slot-die head ends up in the wet film.

The wide diversity of wafer plate sizes and formats challenges the adoption of slot-die coating as a mainstream high throughput industry solution, and several problems arise. The primary approach for slot-die coating wafer plates involves an intermittent process with a high-precision robotic system loading and unloading each wafer into the slot-die tool. In this example, the flow distribution across the slot-die element is interrupted between samples. And a wafer carrier moves back and forward underneath the slot-die while keeping the plate fixed. In this way, each iteration leads to rectangular coating areas with boundaries transverse to the coating direction. However, suppose the target wafer plate size is smaller than the rectangular coating. In that case, a problem arises when the solution diffuses underneath, creating cross-contamination, unwanted chemical reactions, or additional cleaning steps. A cleaning routine of the wafer holder coated area between samples avoids further contamination. The case where the coating area is adjusted to fit the area of the wafer plate is also complex and only applies square substrates. For the two examples mentioned above, the need for intermittent switching of the solution supply and the vertical retrieving of the slot-die head for loading and unloading may result in unwanted homogeneity effects, for instance, the so-called trailing and leading effects at the beginning and end of each intermittent coating. Inconsistencies in the ink volume accumulated on the slot-die cavity or the formed meniscus cause these defects and other deviations in the pre-metered process quality.

Various strategies to avoid leading and trailing inhomogeneities are described. For example, U.S. Pat. Nos. 5,536,313 and 7,041,336 propose complicated designs on the meniscus guide cavity to better control the flow-rate out of the slot-die head. U.S. Pat. No. 6,475,282 proposes a high-resolution control on the flow rate of the solution entering the slot-die head system. Unfortunately, the retained volume due to capillarity or surface effects is persistent, whether with complex nozzle architectures or high hydraulic control. Alternatively, another approach, as described in U.S. Pat. No. 6,436,472, uses a slot-die spin-coating hybrid mechanism where the solution is distributed with a slot-die coating head before spin-coating. Although this approach introduces an innovative protocol for better distributing the solution across the substrate, the process retains all the limitations of slot-die coating regarding material, waste, thickness, and scalability. In the current scenario, it is necessary to consider the extrapolation into production lines capable of producing thousands of wafer coatings per hour at a minimum operational and capital cost.

TW 202015818 A discloses a slot-die head coating system for applying a fluid discharged from the slot-die head to one or more substrates. The system comprises a slot-die head with a discharge slot or slit and a conveyor belt or carrier, wherein the one or more substrates are arranged on the conveyor belt and passes right below the discharge slot of the slot-die head when being coated by the fluid discharged from the slot-die head. The slot-die head has two fixed side rods, and two movable side rods. The fixed side rods are located on both sides of the discharge slot, wherein the distance between the two fixed side rods is equal to the width of the discharge slot. The movable side rods are adjacent to the discharge slot and may move along the width direction of the discharge slot. Thus, the width of the discharge slot may be adjusted and changed at any time; specifically, the slot-die head is divided by the movable side rods into a middle portion and two side portions, wherein the width of the middle portion may be changed along with the shape of the substrate being coated corresponding to the interval of the movable side rods. However, the disclosed slot-die head has no meniscus guide, and the conveyor belt carrying the substrates is not provided with an adhesive front surface for providing a substantially sealed connection between the back surface of the substrates and the front surface of the conveyor belt.

Thus, there is a need for an improved slot-die coating method and system, which allows substrates or wafers of different sizes to be coated without contamination of the back surface of the substrate or wafers. There is also a need for a slot-die coating process and system which allows a continuous throughput of substrates or wafers.

### SUMMARY

It is an object of the present disclosure to provide an improved method for performing a slot-die coating of one or more substrates without contamination of the back surface of the substrates.

It is also an object the present disclosure to provide an improved method for performing a slot-die coating of several substrates which allows a continuous throughput of substrates. This object is achieved in accordance with a first aspect by providing a method for applying a fluid discharged from a slot-die head to one or more substrates, said slot-die head holding a discharge slot and a meniscus guide with a bottom part of the meniscus guide extending below the discharge slot, and said substrate(s) having a front surface, a back surface, edge surfaces between the front and back surfaces, a maximum width, a maximum length, and a thickness; wherein the method comprises:
a) providing an adhesive carrier tape having an adhesive front surface and a non-adhesive back surface;
b) positioning the one or more substrates on the front surface of the carrier tape;
c) providing a substantially sealed connection between the back surface of the one or more substrates and the front surface of the carrier tape;
c) positioning the carrier tape holding the one or more substrates adjacent the slot-die head to define a predetermined distance between the front surface of the carrier tape and a bottom edge of the bottom part of the meniscus guide; and
d) advancing the carrier tape with the one or more substrates in a machine direction past the discharge slot of the slot-die head while discharging the fluid from the discharge slot as a wet film layer on the front surface of the one or more substrates.

In a possible implementation form of the first aspect, the distance between the carrier tape's front surface and the meniscus guide's bottom edge is larger than the substrate's thickness of the substrate(s).

In a possible implementation form of the first aspect, the distance between the front surface of the carrier tape and the bottom edge of the meniscus guide is determined based on the thickness of the substrate(s).

In a possible implementation form of the first aspect, the slot-die head holds a slot-die backplate, a slot-die front plate, a shim, and the meniscus guide, with the shim and meniscus guide sandwiched between the slot-die front and back plates.

In a possible implementation form of the first aspect, the discharge slot has a length defined by the length of an opening in the shim and a width defined by the thickness of the shim.

In a possible implementation form of the first aspect, the one or more substrates are one or more wafers.

In a possible implementation form of the first aspect, the one or more substrates are positioned on the carrier tape to be advanced past the discharge slot in the lengthwise direction of the substrate(s), and the discharge slot extends along the width of the substrate(s) and has an extension larger than the maximum width of the substrate(s).

In a possible implementation form of the first aspect, the discharging of fluid from the discharge slot to the one or more substrates in step d) is performed so as to cover the whole front surface of the substrate(s) and so as to cover the edge surfaces of the substrate(s).

Thus, the whole front surface of a substrate is covered by a wet film layer, which also covers the edges of the substrate. By having a sealed connection between the back surface of a substrate and the carrier tape, the back surface of the substrate is protected from the fluid forming the wet film layer to thereby avoid potential chemical reactions between any functional layer on the back surface of the substrate and components of the fluid forming the wet film layer.

In a possible implementation form of the first aspect, several separate substrates are consecutively positioned on the front surface of the adhesive carrier tape with a distance between each substrate.

In a possible implementation form of the first aspect, the carrier tape with the substrates is continuously advanced in the machine direction for a time period which allows discharging of the fluid from the discharge slot as a wet film layer on the front surface of several of the consecutively positioned substrates.

In a possible implementation form of the first aspect, the fluid is continuously discharged from the discharge slot during said time period whereby a wet film layer is provided both at the front surface of the substrates and on parts of the carrier tape, which carrier tape parts separates the substrates from each other.

In a possible implementation form of the first aspect, the one or more substrates are positioned in a substantially horizontal position on the front surface of the carrier tape, and the carrier tape is advanced in a substantially horizontal direction past the discharge slot.

In a possible implementation form of the first aspect, an alignment support is provided for supporting the back surface of the carrier tape during at least part of step d) to maintain said predetermined distance between the front surface of the carrier tape and the bottom edge of the meniscus guide when discharging the fluid from the discharge slot onto the substrate(s).

In a possible implementation form of the first aspect, the alignment support is a vacuum chuck, said vacuum chuck providing a negative pressure between the vacuum chuck and the carrier tape to planarize the substrate(s) sealed to the carrier tape during discharging of the fluid from the discharge slot onto the substrate(s).

In a possible implementation form of the first aspect, the size of the negative pressure is selected to allow the carrier tape to be advanced in the machine direction on top of the vacuum chuck.

In a possible implementation form of the first aspect, the method further comprises a step of deactivating the sealed connection between the one or more substrates and the adhesive carrier tape.

In a possible implementation form of the first aspect, the adhesive carrier tape is a light-curable tape, and light from a light radiation source is radiated into the back surface of the carrier tape below the substrate(s) positioned on the front surface of the carrier tape after the substrate(s) has fully passed the discharge slot, thereby inhibiting or deactivating the connection between the one or more substrates and the adhesive carrier tape.

Light curing uses light, such as ultra-violet light, to deactivate the adhesive strength of the carrier tape and facilitates separation of the substrate from the carrier tape.

In a possible implementation form of the first aspect, the light radiation source is arranged below the carrier tape and a light trap structure is provided above the light radiation source with the carrier tape holding the substrate(s) passing in the machine direction in between the light radiation source and the light trap structure.

In a possible implementation form of the first aspect, the light radiation source is arranged downstream of the slot-die head and the alignment support with reference to the machine direction.

In a possible implementation form of the first aspect, the adhesive carrier tape is a heat-sensitive tape, and step c) of providing a sealed connection between the back surface of the substrate(s) and the front surface of the carrier tape includes a heating process by use of a first heat source in which heat is supplied to the back surface of the carrier tape below the substrate(s) positioned on the front surface of the carrier tape.

In a possible implementation form of the first aspect, the first heat source is arranged upstream of the slot-die head and the alignment support with reference to the machine direction.

In a possible implementation form of the first aspect, heat is supplied by a second heat source to the back surface of the carrier tape below the substrate(s) positioned on the front surface of the carrier tape after the substrate(s) has fully passed the discharge slot, thereby deactivating the sealed connection between the one or more substrates and the adhesive carrier tape.

The heat supplied by the second heat source may deactivate the adhesive strength of the carrier tape and facilitate the separation of the substrate from the carrier tape.

In a possible implementation form of the first aspect, the second heat source is arranged downstream of the slot-die head and the alignment support with reference to the machine direction.

In a possible implementation form of the first aspect, a first transport conveyor belt is provided for feeding several separate substrates to the carrier tape, and a first backing roll is provided for holding the carrier tape in position for receiving the separate substrates from the conveyor belt when the carrier tape is advanced in the machine direction.

In a possible implementation form of the first aspect, the first backing roll is arranged upstream of the slot-die head and the alignment support with reference to the machine direction.

In a possible implementation form of the first aspect, where a first heat source is provided, the first backing roll is arranged upstream of the first heat source with reference to the machine direction.

In a possible implementation form of the first aspect, the method further comprises a step of separating the one or more substrates from the adhesive carrier tape.

In a possible implementation form of the first aspect, the step of deactivating the sealed connection between the one or more substrates and the adhesive carrier tape is followed by the step of separating the substrate(s) from the adhesive carrier tape.

In a possible implementation form of the first aspect, a substrate-tape separation platform and a second backing roll are provided and arranged for separating the substrate(s) from the adhesive carrier tape.

In a possible implementation form of the first aspect, a second transport conveyor belt is provided for receiving the substrate(s) when separated from the adhesive carrier tape, and the substrate-tape separation platform is positioned for feeding the separated substrate(s) to the second conveyor belt.

In a possible implementation form of the first aspect, the second transport conveyor belt is arranged downstream of the substrate-tape separation platform with reference to the machine direction.

In a possible implementation form of the first aspect, the substrate-tape separation platform has a rounded substrate release edge and the second backing roll is positioned to secure that the carrier tape holding the substrate(s) is drawn around the substrate release edge when advancing the carrier tape.

In a possible implementation form of the first aspect, the substrate-tape separation platform and the second backing roll are arranged downstream of the light radiation source or downstream of the second heat source with reference to the machine direction.

In a possible implementation form of the first aspect, the substrate-tape separation platform and the second backing roll are arranged for changing the direction of the adhesive carrier tape by a peeling angle of at least 90 degrees with reference to the machine direction.

It is a further object of the present disclosure to provide an improved system for performing a slot-die coating of one or more substrates without contamination of the back surface of the substrates.

It is also a further object the present disclosure to provide an improved system for performing a slot-die coating of several substrates which allows a continuous throughput of substrates.

This object is achieved in accordance with a second aspect by providing a system for applying a fluid to one or more moving substrates, said substrate(s) having a front surface, a back surface, edge surfaces between the front and back surfaces, a maximum width, a maximum length, and a thickness; wherein the system comprises:
a slot-die head holding a discharge slot and a meniscus guide with a bottom part of the meniscus guide extending below the discharge slot;
an adhesive substrate carrier tape having an adhesive front surface and a non-adhesive back surface, said carrier tape holding the one or more substrates on its front surface, and said carrier tape being configured for providing a substantially sealed connection between the back surface of the one or more substrates and the front surface of the carrier tape;
a roll system for advancing the carrier tape holding the one or more substrates in a machine direction past the discharge slot of the slot-die head; and
an alignment support for supporting the back surface of the carrier tape to maintain a predetermined distance between the front surface of the carrier tape and a bottom edge of the meniscus guide, and thereby to maintain a distance between the front surface of the substrate(s) and the bottom edge of the meniscus guide when advancing the carrier tape holding the one or more substrates in a machine direction past the discharge slot of the slot-die head.

In a possible implementation form of the second aspect, the distance between the carrier tape's front surface and the meniscus guide's bottom edge is larger than the substrate's (s) thickness.

In a possible implementation form of the second aspect, the distance between the front surface of the carrier tape and the bottom edge of the meniscus guide is determined based on the thickness of the substrate(s).

In a possible implementation form of the second aspect, the slot-die head holds a slot-die backplate, a slot-die front plate, a shim, and the meniscus guide, with the shim and meniscus guide sandwiched between the slot-die front and back plates.

In a possible implementation form of the second aspect, the discharge slot has a length defined by the length of an opening in the shim and a width defined by the thickness of the shim.

In a possible implementation form of the second aspect, the one or more substrates are one or more wafers.

In a possible implementation form of the second aspect, the one or more substrates are positioned on the carrier tape to be advanced past the discharge slot in the lengthwise direction of the substrate(s).

In a possible implementation form of the second aspect, the discharge slot extends along the width of the substrate(s) and has an extension larger than the maximum width of the substrate(s).

In a possible implementation form of the second aspect, the slot-die head is configured for discharging the fluid from the discharge slot as a wet film layer on the front surface of the one or more substrates when the carrier tape holding the one or more substrates is advanced in the machine direction past the discharge slot of the slot-die head.

In a possible implementation form of the second aspect, the slot-die head is configured for discharging the fluid from the discharge slot to the one or more substrates so as to cover the whole front surface of the substrate(s) and so as to cover the edge surfaces of the substrate(s).

Thus, the whole front surface of a substrate may be covered by a wet film layer, which also covers the edges of the substrate. By having a sealed connection between the back surface of a substrate and the carrier tape, the back surface of the substrate is protected from the fluid forming the wet film layer to thereby avoid potential chemical reactions between any functional layer on the back surface of the substrate and components of the fluid forming the wet film layer.

In a possible implementation form of the second aspect, several separate substrates are consecutively positioned on the front surface of the adhesive carrier tape with a distance between each substrate.

In a possible implementation form of the second aspect, the roll system is configured for continuously advancing the carrier tape with the substrates in the machine direction for a time period which allows discharging of the fluid from the discharge slot as a wet film layer on the front surface of several of the consecutively positioned substrates.

In a possible implementation form of the second aspect, the one or more substrates are positioned in a substantially horizontal position on the front surface of the carrier tape, and the roll system is configured for advancing the carrier tape in a substantially horizontal direction past the discharge slot.

In a possible implementation form of the second aspect, the alignment support is a vacuum chuck, where the vacuum chuck is configured for providing a negative pressure between the vacuum chuck and the carrier tape to planarize the substrate(s) sealed to the carrier tape when passing the discharge slot.

In a possible implementation form of the second aspect, the size of the negative pressure is selected to allow the carrier tape to be advanced in the machine direction on top of the vacuum chuck.

In a possible implementation form of the second aspect, the system further comprises a deactivating system for deactivating the sealed connection between the one or more substrates and the adhesive carrier tape.

In a possible implementation form of the second aspect, the adhesive carrier tape is a light-curable tape, and the deactivating system holds a light radiation source arranged for supplying light to the back surface of the carrier tape below the substrate(s) positioned on the front surface of the carrier tape.

The supply of light deactivates the adhesive strength of the light-curable carrier tape and facilitates separation of the substrate(s) from the carrier tape.

In a possible implementation form of the second aspect, the light radiation source is arranged downstream of the slot-die head and the alignment support with reference to the machine direction.

In a possible implementation form of the second aspect, the light radiation source is arranged below the carrier tape, and a light trap structure is provided above the light radiation source with the carrier tape holding the substrate(s) passing in the machine direction in between the light radiation source and the light trap structure.

In a possible implementation form of the second aspect, the adhesive carrier tape is a heat-sensitive tape, and the system further comprises a first heat source for supply of heat to the back surface of the carrier tape below the substrate(s) positioned on the front surface of the carrier tape.

In a possible implementation form of the second aspect, the first heat source is arranged upstream of the slot-die head and the alignment support with reference to the machine direction.

In a possible implementation form of the second aspect, the deactivating system comprises a second heat source arranged for supply of heat to the back surface of the carrier tape below the substrate(s) positioned on the front surface of the carrier tape.

The heat supplied from the second heat source may deactivate the adhesive strength of the heat-sensitive carrier tape and facilitate the separation of the substrate from the carrier tape.

In a possible implementation form of the second aspect, the second heat source is arranged downstream of the slot-die head and the alignment support with reference to the machine direction.

In a possible implementation form of the second aspect, the system further comprises:
a first transport conveyor belt for feeding several separate substrates to the carrier tape, and
a first backing roll for holding the carrier tape in position for receiving the separate substrates from the conveyor belt when the carrier tape is advanced in the machine direction.

In a possible implementation form of the second aspect, the first backing roll is arranged upstream of the slot-die head and the alignment support and if there is a the first heat supply, also upstream the first heat supply with reference to the machine direction.

In a possible implementation form of the second aspect, the first transport conveyor belt is positioned upstream the first backing roll with reference to the machine direction.

In a possible implementation form of the second aspect, the system further comprises a separating system for separating the one or more substrates from the adhesive carrier tape.

In a possible implementation form of the second aspect, the separating system comprises a substrate-tape separation platform and a second backing roll.

In a possible implementation form of the second aspect, the system further comprises a second transport conveyor belt for receiving the substrate(s) when separated from the adhesive carrier tape, and the substrate-tape separation platform is positioned for feeding the separated substrate(s) to the second conveyor belt.

In a possible implementation form of the second aspect, the second transport conveyor belt is arranged downstream of the substrate-tape separation platform with reference to the machine direction.

In a possible implementation form of the second aspect, the substrate-tape separation platform has a rounded substrate release edge, and the second backing roll is positioned to secure that the carrier tape holding the substrate(s) is drawn around the substrate release edge when the carrier tape is advanced.

In a possible implementation form of the second aspect, the substrate-tape separation platform and the second backing roll are arranged downstream of the light radiation source or downstream of the second heat source with reference to the machine direction.

In a possible implementation form of the second aspect, the substrate-tape separation platform and the second backing roll are arranged for changing the direction of the adhesive carrier tape by a peeling angle of at least 90 degrees with reference to the machine direction.

The foregoing and other objects are achieved by the features of the independent claims. Further implementation forms are apparent from the dependent claims, the description and the figures. These and other aspects of the invention will be apparent from the embodiments described below.

### BRIEF DESCRIPTION OF THE DRAWINGS

In the following detailed portion of the present disclosure, the invention will be explained in more detail with reference to the example embodiments shown in the drawings, in which:

FIG. 1a is an isometric view of an assembled slot-die head according to an example embodiment;

FIG. 1b is an exploded view of the slot-die head of FIG. 1a according to an example embodiment;

FIG. 1c is a left side view of the assembled slot-die head of FIG. 1a according to an example embodiment;

FIG. 1d is a front view of the assembled slot-die head of FIG. 1a according to an example embodiment;

FIG. 1e is a close-up view of part of the bottom of the slot-die head of FIG. 1d according to an example embodiment;

FIG. 2a illustrates a roll-to-substrate slot-die coating system using light-curable adhesive carrier tape according to an example embodiment;

FIG. 2b illustrates a roll-to-substrate slot-die coating system using heat-sensitive adhesive carrier tape according to an example embodiment;

FIG. 3a is a schematic top view of a roll-to-substrate slot-die coating system using a carrier tape and slot-die coating width for coating one substrate at a time according to an example embodiment;

FIG. 3b is a schematic top view of a roll-to-substrate slot-die coating system using a carrier tape and slot-die coating width for coating two substrate simultaneously according to an example embodiment;

FIG. 4a is a close-up view of transfer of a texturized substrate from a feeding transport conveyor belt onto an adhesive carrier tape according to an example embodiment;

FIG. 4b is a close-up view of transfer of a flat substrate from a feeding transport conveyor belt onto an adhesive carrier tape according to another example embodiment;

FIGS. 5a and 5b are schematic side views illustrating a coating process of a substrate being moved relative to a coating slot-die head according to an example embodiment;

FIG. 5c is a cut-out view illustrating coating of a substrate having a textured bottom surface according to an example embodiment;

FIG. 5d is a cut-out view illustrating coating of a substrate having a flat bottom surface according to an example embodiment;

FIGS. 6a and 6b are schematic close-up side and top views illustrating an arrangement of a slot-die head and vacuum chuck within a roll-to-substrate slot-die coating system according to an example embodiment;

FIG. 7 is a flow-chart illustrating steps of a roll-to-substrate slot-die coating process using light-curable adhesive carrier tape according to an example embodiment; and

FIG. 8 is a flow-chart illustrating steps of a roll-to-substrate slot-die coating process using heat-sensitive adhesive carrier tape according to an example embodiment.

### LIST OF REFERENCE NUMBERS FOR THE DRAWINGS

100 Slot-die head.
101 Slot-die backplate.
102 Meniscus guide.
103 Shim.
104 Slot-die front plate.
105 Front plate fasteners.
106 Backplate fasteners.
107 Surface of substrate to be coated.
108 Width of bottom part of meniscus guide.
109 Distance between meniscus guide and substrate to be coated.
110 Length of shim and meniscus guide.
111a Slot-die head manifold ink reservoir and ink inlet.
111b Discharge slot.
200a Roll-to-substrate slot-die coating system using light-curable adhesive carrier tape.
200b Roll-to-substrate slot-die coating system using heat-sensitive adhesive carrier tape.
201 First transport conveyor belt.
202 Substrate.
202a Substrate with textured bottom surface.
202b Substrate with flat bottom surface.
203 First backing roll.
204 Adhesive carrier tape.
205 Direction of advancement of carrier tape drawn by the first backing roll.
206 Merging point between carrier tape and substrate.
207a Upstream meniscus formed between meniscus guide and substrate.
207b Upstream meniscus formed between meniscus guide and carrier tape.
208 Coated wet film layer.
208a Coated wet film layer on front surface of substrate.
208b Coated wet film layer on front surface of adhesive carrier tape.
208ca Coated wet film layer at edge between substrate with textured bottom layer and carrier tape.
208cb Coated wet film layer at edge between substrate with flat bottom layer and carrier tape.
209 Vacuum chuck.
209a Vacuum chuck metallic solid frame component.
209b Vacuum chuck metallic porous material.
210 Light radiation source for curing carrier tape.
211 Light trap structure avoiding the coated wet film from exposure to stray light from light source 210.
212 Machine direction of advancement of carrier tape past coating slot-die head.
213 Remaining coated film layer on carrier tape.
214 Peeling angle
215 Substrate tape separation platform.
216 Second backing roll.
217 Direction of advancement of carrier tape drawn by the second backing roll.
218 Separation point between carrier tape and substrate.
219 Second transport conveyor belt.
220 Coated and separated substrate.
221 First heat source for activating adhesive strength of heat-sensitive carrier tape.
222 Second heat source for deactivating adhesive strength of heat-sensitive carrier tape.
223 Adhesive layer of carrier tape. Thickness larger than roughness of textured substrate bottom surface.
224 Adhesive carrier tape base film.
225 Distance between meniscus guide and top surface of adhesive carrier tape
226 Cut-out view of wet film layer between edge of substrate and carrier tape.
226a Cut-out view of wet film layer at edge between substrate with textured bottom layer and carrier tape.
226b Cut-out view of wet film layer at edge between substrate with flat bottom layer and carrier tape.

### DETAILED DESCRIPTION

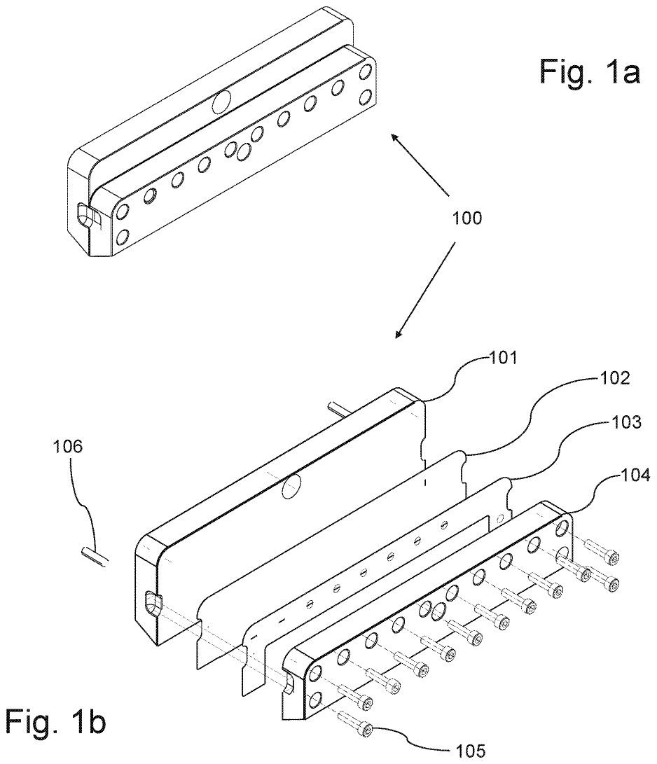

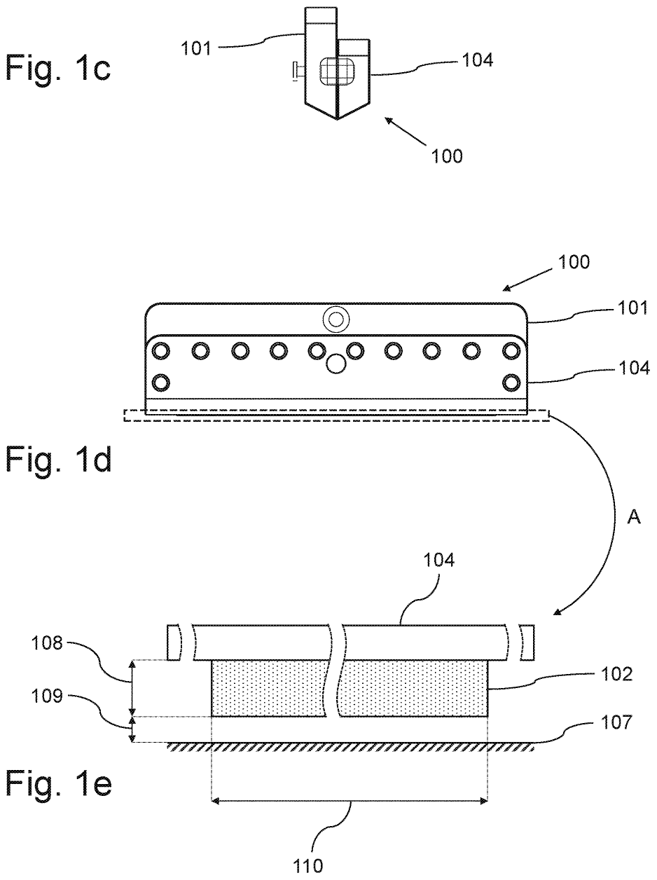

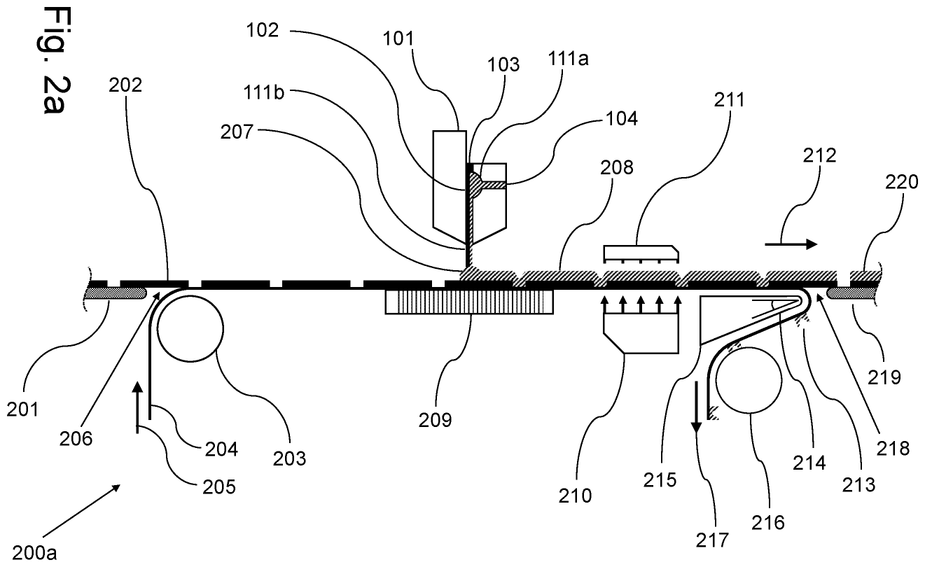

In order to perform a slot-die coating, a slot-die coating system shall be provided, where the slot-die coating system holds a slot-die head 100 as illustrated in FIG. 1a, b, c, and d. Here FIG. 1a is an isometric view of a fully assembled slot-die head 100 according to an embodiment, FIG. 1b is an exploded view of the slot-die head 100, FIG. 1c is a left side view and FIG. 1d is a front view of the assembled slot-die head 100.

The slot-die head 100 comprises a slot-die backplate 101, a meniscus guide 102, a shim 103, and a slot-die front plate 104. The meniscus guide 102 and the shim 103 are sandwiched between the backplate 101 and the front plate 104, and front plate fasteners 105 and backplate fastener 106 are provided for assembling the backplate 101, the meniscus guide 102, the shim 103, and the front plate 104.

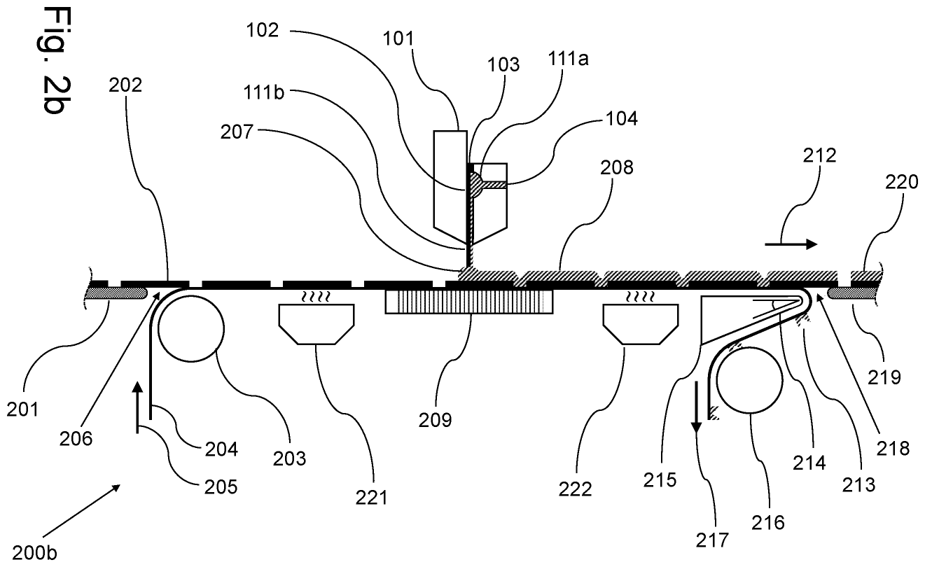

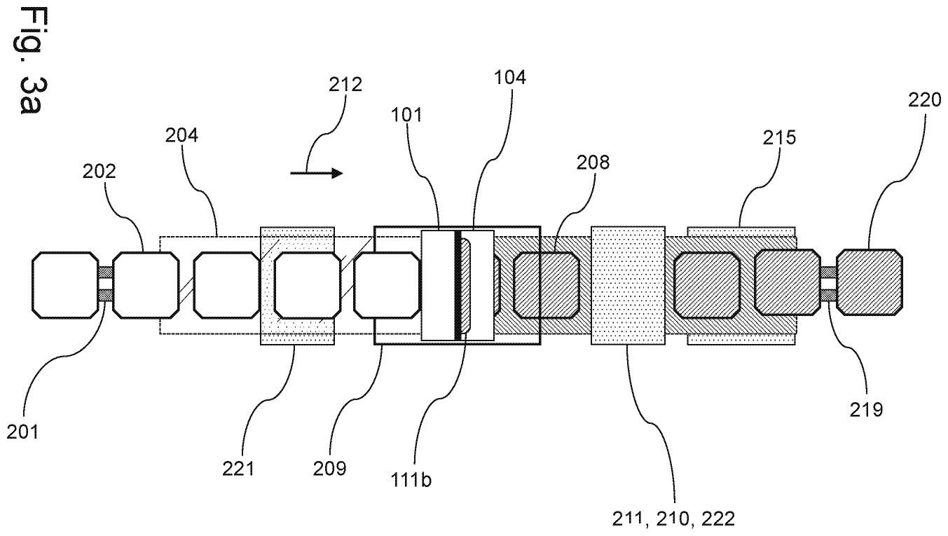

A slot-die head ink reservoir with an ink inlet 111a (see FIGS. 2a, 2b, 5a, 5b and 6a) is formed in the front plate 104, which ink reservoir is fluidly connected to a discharge slot 111b (see FIGS. 2a, 2b, 5a, 5b and 6a) formed in the front plate 104 at the bottom of the slot-die head 100. The discharge slot 111b has a length defined by the length of an opening in the shim 103 and a width defined by the thickness of the shim 103.

The meniscus guide 102 has a bottom part extending below the discharge slot 111b, as illustrated in FIG. 1e, which is a close-up view of part of the bottom of the slot-die head 100 shown in FIG. 1d as indicated by arrow A. In FIGS. 1e, 108 indicates the width of the bottom part of the meniscus guide 102 extending below the discharge slot 111b and the front plate 104 of the slot-die head 100, 107 indicates a surface of a substrate to be coated, 109 indicates the distance between a bottom edge of the meniscus guide 102 and the surface 107 of the substrate to be coated, and 110 indicates the length of the shim 103 and the length of the meniscus guide 102.

In order to coat a wet film layer on a substrate by use of the slot-die head 100, the slot-die coating system may hold a pumping element driving a fluid solution into the slot-die head ink reservoir 111a, from where the solution is guided by the meniscus guide 102 through the discharge slot downwards onto the target substrate 107. A combination of a continuous flow feeding the slot-die head ink reservoir 111a and a moving substrate creates a wet film with a width equal to the length 110 of the meniscus guide 102. The wet film thickness is directly proportional to the pump rate and inversely proportional to the extension of the meniscus guide 102 and the velocity at which the substrate moves.

FIG. 2a illustrates a so called “roll-to-substrate” slot-die coating system 200a using light-curable adhesive carrier tape for carrying substrates 202 to be coated, while FIG. 2b illustrates a so called “roll-to-substrate” slot-die coating system 200b using heat-sensitive adhesive carrier tape. The systems of FIG. 2a and FIG. 2b hold a number of identical components, which are therefore referred to by the same reference numbers.

The systems 200a and 200b of FIGS. 2a and 2 both hold a slot-die head 100 as described in connection with FIGS. 1a to 1e, where the slot-die head 100 has a slot-die backplate 101, a meniscus guide 102, a shim 103, and a slot-die front plate 104, and where a slot-die head ink reservoir with an ink inlet 111a is formed in the front plate 104, which ink reservoir is fluidly connected to a discharge slot 111b formed in the front plate 104 at the bottom of the slot-die head 100. The discharge slot 111b has a length defined by the length of an opening in the shim 103 and a width defined by the thickness of the shim 103. The meniscus guide 102 has a bottom part extending below the discharge slot 111b.

For both systems 200a and 200b, a roll system holding a first backing roll 203 and a second backing roll 216 is provided for advancing an adhesive carrier tape 204, which holds one or more substrates 202, in a machine direction 212 past the discharge slot 111b and the bottom part of the meniscus guide 102 extending below the discharge slot 102 of the slot-die head 100. The adhesive substrate carrier tape 204 has an adhesive front surface and a non-adhesive back surface. The carrier tape 204 holds the substrates on its front surface, where a substantially sealed connection between the back surface of the substrates 202 and the front surface of the carrier tape 204 can be provided due to the adhesive front surface of the carrier tape 204.

A first transport conveyor belt 201 is arranged for feeding the substrates 202 onto the adhesive carrier tape and a second transport conveyor belt 219 is arranged for receiving the substrates 202 after a wet film layer 208 has been coated onto the substrates 202 when passing the discharge slot 111b of the slot-die head 100 and after the substrates have been separated from the carrier tape 204. When advancing the carrier tape 204 with a substrate 202 in the machine direction 212 past the discharge slot 111b of the slot-die head 100 while discharging fluid from the discharge slot 111b as a wet film layer 208 on the front surface of the substrate 202, an upstream meniscus 207 is formed between the meniscus guide 102 and the substrate 202. In FIGS. 2a and 2b, the numeral 220 refers to a coated and separated substrate received by the second transport conveyor belt 219.

An alignment support 209 is arranged below the slot-die head 100 for supporting the back surface of the carrier tape 204 and to maintain a predetermined distance between the front surface of the carrier tape 204 and a bottom edge of the meniscus guide 102, and thereby to maintain a predetermined distance between the front surface of the substrate 202 and the bottom edge of the meniscus guide 102 when advancing the carrier tape 204 holding the one or more substrates in a machine direction past the discharge slot of the slot-die head. It should be understood that the distance between the carrier tape's front surface 204 and the meniscus guide's bottom edge 102 is larger than the thickness of the substrates 202. It is preferred that the substrates 202 are wafers, such as silicon wafers. The substrates 202 may be positioned on the carrier tape 204 to be advanced past the discharge slot in the lengthwise direction of the substrates 202.

The discharge slot 111b and the meniscus guide 102 of the slot-die head 100 may be configured for discharging the fluid from the discharge slot 111b to the substrates 202 so as to cover the whole front surface of the substrates 202 and so as to cover the edge surfaces of the substrates 202. Thus, the discharge slot 111b extends along the width of the substrates 202 and should have has an extension larger than the maximum width of the substrates 202.

The substrates 202 are positioned in a substantially horizontal position on the front surface of the carrier tape 204, and the roll system is configured for advancing the carrier tape in a substantially horizontal direction past the discharge slot 111b. It is preferred that several separate substrates 202 are consecutively positioned on the front surface of the adhesive carrier tape 204 with a distance between each substrate 202. The roll system may be configured for continuously advancing the carrier tape 204 with the substrates 202 in the machine direction 212 for a time period, which allows discharging of the fluid from the discharge slot 111b as a wet film layer on the front surface of several of the consecutively positioned substrates 202.

It is preferred that the alignment support 209 is a vacuum chuck configured for providing a negative pressure between the vacuum chuck and the carrier tape 204 to planarize the substrates 202 sealed to the carrier tape when passing the discharge slot 111b. The size of the negative pressure may be selected to allow the carrier tape 204 to be advanced in the machine direction 212 on top of the alignment support 209. Here, the negative pressure may be in the range of 2-6 bars, such as in the range of 3-4 bars.

In order to separate the coated substrates 202 from the carrier tape 204, a substrate tape separation platform 215 is provided. The tape separation platform 215 is positioned above the second backing roll 216 to change the direction of the carrier tape by a peeling angle 214, which is at least 90 degrees, and which allows a separation of the substrates 202 from the carrier tape 204. When the substrate 202 has been separated from the carrier tape 204, part of the coated film layer remains on the carrier tape 204 as indicated by numeral 213.

In FIGS. 2a and 2b, the numeral 205 refers to the direction of advancement of the carrier tape 204 when entering the first backing roll 203, and the numeral 206 refers to a merging point between the carrier tape 204 and a substrate 202 when received from the first transport conveyor belt 201. The numeral 217 refers to the direction of advancement of the carrier tape 204 when leaving the second backing roll 216, and the numeral 218 refers to a separation point between the carrier tape 204 and a substrate 202.

The system 200a of FIG. 2a is designed for using a light-curable adhesive carrier tape 204, such as an Ultra-Violet, UV, light curable adhesive tape, where the adhesive strength between the carrier tape 204 and the substrates 202 can be deactivated by exposing the carrier tape to light, such as UV light. The system 200a therefore holds a deactivating system in the form of a light radiation source 210 arranged for supplying light to the back surface of the carrier tape 204 below the substrates 202 positioned on the front surface of the carrier tape 204. The light radiation source 210 is arranged downstream of the slot-die head 100 and the alignment support 209 with reference to the machine direction 212. A light trap structure 211 may be provided above the light radiation source 210 with the carrier tape 204 holding the substrates 202 passing in the machine direction 212 in between the light radiation source 210 and the light trap structure 211. The light trap structure 211 may prevent scattered light from the light radiation source 201 to impinge the wet film layer 208 coated on top of the substrates 202.

For the system 200a of FIG. 2a the substrate-tape separation platform 215 and the second backing roll 216 are arranged downstream of the light radiation source 210 with reference to the machine direction 212, and the second transport conveyor belt 219 is arranged downstream of the substrate-tape separation platform 215 with reference to the machine direction.

The system 200b of FIG. 2b is designed for using a heat-sensitive adhesive carrier tape 204. The system 200b of FIG. 2b therefore holds a first heat source 221 for activating the adhesive strength of the heat-sensitive carrier tape 204. The first heat source 221 is positioned for supply of heat to the back surface of the carrier tape 204 below the substrates 202 positioned on the front surface of the carrier tape 204. The first heat source 2021 is arranged upstream of the slot-die head 100 and the alignment support 209 with reference to the machine direction 212. The heat-sensitive adhesive carrier band 204 may have a glue top layer, which is softened by a heat treatment provided by the first heat source 221, to thereafter re-solidify and hold the substrates 202 in a secure position. In order to separate the coated substrates 202 from the heat-sensitive carrier tape 204, it may be needed to soften the solidified top layer glue by a second heat treatment. Thus, a deactivating system in the form of a second heat source 222 is arranged for supply of heat to the back surface of the heat-sensitive carrier tape 204 below the substrates 202 positioned on the front surface of the carrier tape. The second heat source 222 is arranged downstream of the slot-die head 100 and the alignment support 209 with reference to the machine direction 212.

For the system 200b of FIG. 2b the substrate-tape separation platform 215 and the second backing roll 216 are arranged downstream of the second heat source 222 with reference to the machine direction 212, and the second transport conveyor belt 219 is arranged downstream of the substrate-tape separation platform 215 with reference to the machine direction.

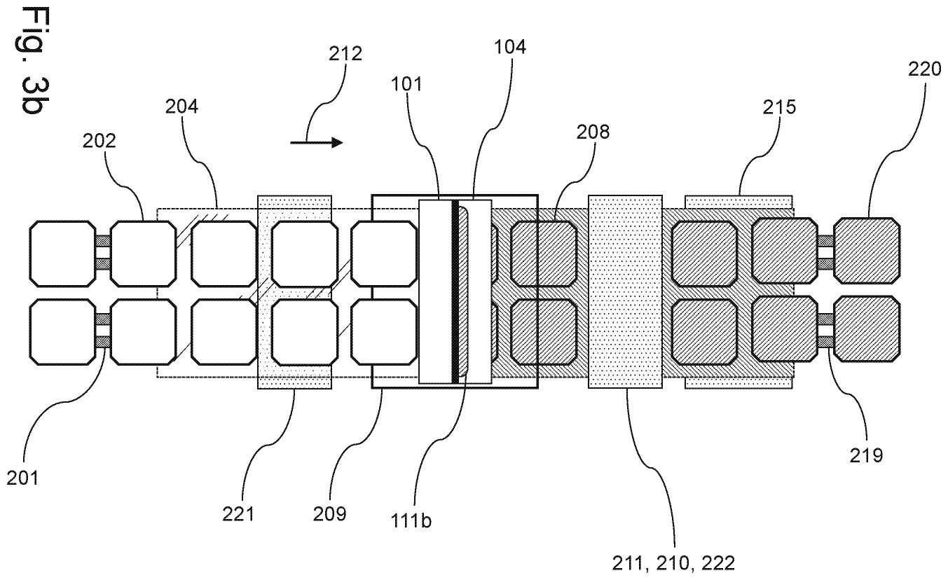

It is within an embodiment of the present disclosure that the carrier tape 204 may carry a single row of substrates 202, but is also within an embodiment of the present disclosure that the carrier tape 204 carries two or more rows of substrates 202. This is illustrated in FIGS. 3a and 3b, in which FIG. 3a is a schematic top view of a “roll-to-substrate” slot-die coating system 200a or 200b using a carrier tape 204 and slot-die coating width for coating one substrate 202 at a time. It is seen that the discharge slot 111b of FIG. 3a has an extension larger than the maximum width of a single substrate 202. In case, where FIG. 3a represents the system 200a, there are no first and second heat sources 211 and 220, while the system 200a has a light radiation source 210 and a light trap structure 211. In case, where FIG. 3a represents the system 200b, there are first and second heat sources 211 and 220, while the system 200b has no light radiation source 210 and no light trap structure 211.

FIG. 3b is a schematic top view of a “roll-to-substrate” slot-die coating system using a carrier tape 204 and slot-die coating width for coating two substrates 202 simultaneously. It is seen that the discharge slot 111b of FIG. 3b has an extension larger than the maximum width of two parallel arranged substrates 202. In case, where FIG. 3b represents the system 200a, there are no first and second heat sources 211 and 220, while the system 200a has a light radiation source 210 and a light trap structure 211. In case, where FIG. 3b represents the system 200b, there are first and second heat sources 211 and 220, while the system 200b has no light radiation source 210 and no light trap structure 211.

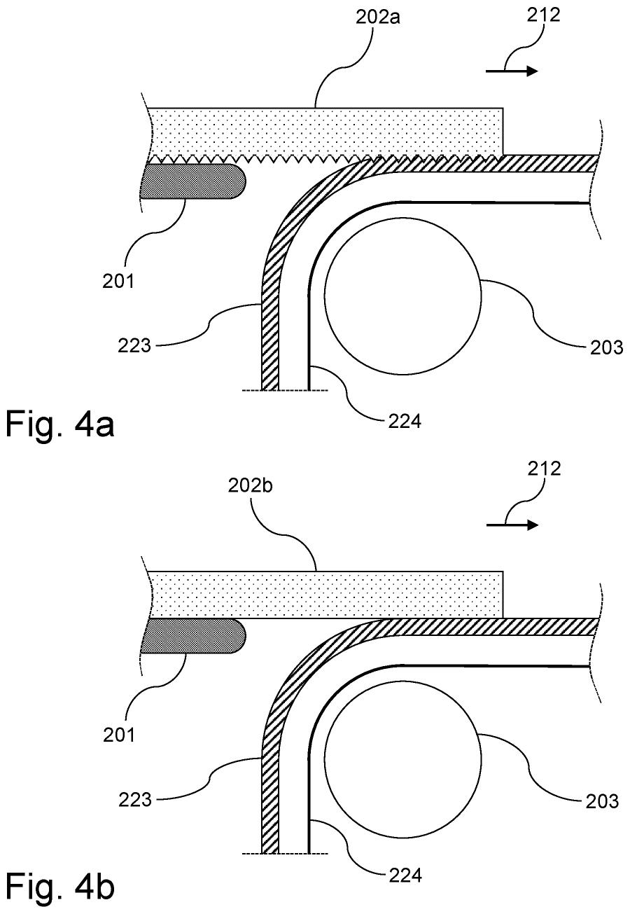

The substrates or wafers 202 being processed by the systems 200a or 200b may have different formation of the surfaces of the bottom part. This is illustrated in FIGS. 4a and 4b, in which FIG. 4a is a close-up view of transfer of a texturized substrate 202a from a feeding transport conveyor belt 201 onto an adhesive carrier tape 204, and where FIG. 4b is a close-up view of transfer of a flat substrate 202b from a feeding transport conveyor belt 201 onto an adhesive carrier tape 204. In FIGS. 4a and 4b, the carrier tape 204 is shown as a two-layer carrier tape having an adhesive top layer 223 on top of a carrier tape base film 224. The thickness of the adhesive top layer 223 shall be larger than the roughness of textured substrate bottom surface of the substrate 202a.

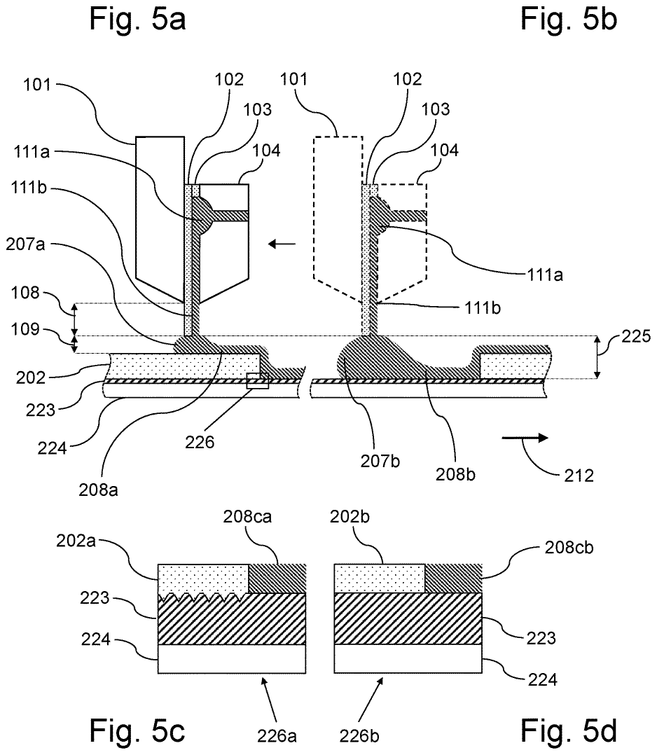

The substrates or wafers 202 being processed by the systems 200a or 200b are advanced in the machine direction 212 past the discharge slot 111b of the slot-die head 100 while fluid is discharged as a wet film layer 208a on front of the substrates or wafers 202. This is illustrated in FIGS. 5a and 5b, which are schematic side views illustrating a coating process of a substrate 202 being moved relative to the coating discharge slot 111b of the slot-die head 100.

The slot-die head 100 has a slot-die backplate 101, a meniscus guide 102, a shim 103, and a slot-die front plate 104. A slot-die head ink reservoir with an ink inlet 111a is formed in the front plate 104, which ink reservoir is fluidly connected to the discharge slot 111b formed in the front plate 104 at the bottom of the slot-die head 100. The substrates 202 are sealed to a two-layer carrier tape having and adhesive top layer 223 on top of a carrier tape base film 224 and moved in a machine direction 212 past the discharge slot 111b by advancement of the carrier tape. The carrier tape with the substrates 202 may be moved at a constant speed while the slot-die head 100 remains at a fixed position.

FIG. 5a illustrates a first part of a coating process, in which a wet film layer 208a has been coated on part of the front surface of a substrate 202. In order to obtain a desired thickness of the coated wet film layer 208a, the slot-die head 100 is positioned so as to define a predetermined distance 225 between a bottom edge of the meniscus guide 102 and a top surface of the adhesive carrier tape 223. In order to guide the fluid discharged on the substrate 202, a bottom part of the meniscus guide 102 having a width 108, as indicated in FIG. 5a, extends below the discharge slot 111b. In FIG. 5a, the numeral 109 indicates the distance between the bottom edge of the meniscus guide 102 and the substrate being coated 202. During discharge of fluid on the substrate 202, an upstream meniscus 207a is formed between the bottom edge of the meniscus guide 102 and the substrate 202.

FIG. 5b illustrates a second part of the coating process, in which the substrate 202 has passed the discharge slot 111b, and fluid is now discharged directly on the top layer 223 of the carrier tape, with a coated wet film 208b layer being formed on the top layer 223 of the carrier tape. During discharge of fluid on the top layer 223 of the carrier tape, an upstream meniscus 207b is formed between the bottom edge of the meniscus guide 102 and the top layer 223 of the carrier tape.

In FIG. 5a, numeral 226 indicates a cut out of the sealing between the tope surface 223 of the carrier tape and the edge of a coated substrate 202. This is further illustrated in FIGS. 5c and 5d, in which FIG. 5c is a cut-out view 226a illustrating coating of a substrate 202a having a textured bottom surface sealed to the adhesive top layer 223 on top of the carrier tape base film 224, with a coated wet film layer 208ca formed at the edge of the substrate 202. FIG. 5d is a cut-out view 226b illustrating coating of a substrate 202b having a flat bottom surface sealed to the adhesive top layer 223 on top of the carrier tape base film 224, with a coated wet film layer 208cb formed at the edge of the substrate 202.

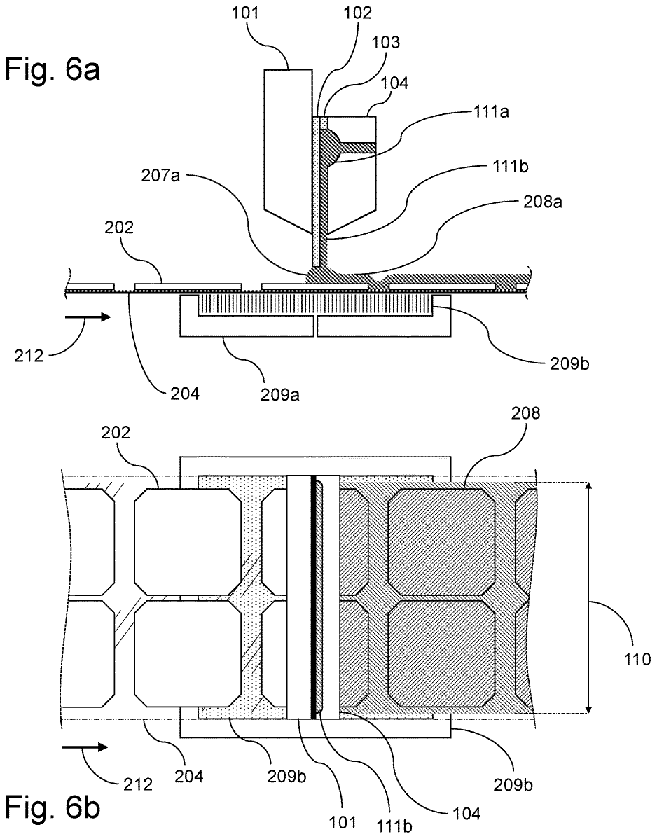

As discussed in connection with FIGS. 2a and 2b, the systems 200a and 200b both holds an alignment support 209, which is arranged below the slot-die head 100 for supporting the back surface of the carrier tape 204 and for maintaining a predetermined distance between the front surface of the carrier tape 204 and a bottom edge of the meniscus guide 102. It is preferred that the alignment support 209 is a vacuum chuck type support as further illustrated in FIGS. 6a and 6b, which are schematic close-up side and top views illustrating an arrangement of a slot-die head 100 and a vacuum chuck 209 within a roll-to-substrate slot-die coating system 200a, 200b.

In FIGS. 6a and 6b, the slot-die head 100 has a slot-die backplate 101, a meniscus guide 102, a shim 103, and a slot-die front plate 104. A slot-die head ink reservoir with an ink inlet 111a is formed in the front plate 104, which ink reservoir is fluidly connected to the discharge slot 111b formed in the front plate 104 at the bottom of the slot-die head 100. The substrates 202 are sealed to the adhesive carrier tape 204 and moved in a machine direction 212 past the discharge slot 111b on top of the vacuum chuck 209, which has a vacuum chuck metallic solid frame component 209a, which forms a frame around a vacuum chuck metallic porous material 209b. The vacuum chuck metallic porous material 209b enables laminar flow for maximum flatness of the carrier tape 204 and substrate 202 while coating. The system illustrated in FIG. 6b uses a carrier tape 204 and slot-die coating width for coating two substrates 202 simultaneously. It is seen that the discharge slot 111b has an extension larger than the maximum width of two parallel arranged substrates 202. The extension of the discharge slot 111b is defined by the length 110 of the shim 103 and meniscus guide 102. FIG. 6b also shows that the width of the vacuum chuck metallic porous material 209b is substantially equal to the width of the carrier tape 204.

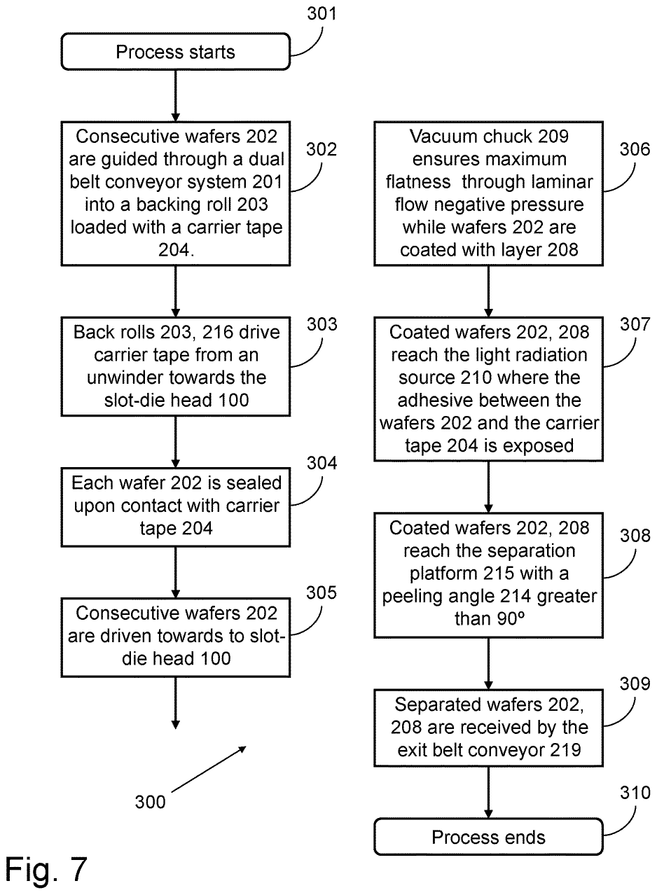

FIG. 7 is a flow-chart illustrating steps of a roll-to-substrate slot-die coating process performed by use of the system 200a of FIG. 2a and using a light-curable adhesive carrier tape 204 and substrates in the form of silicon wafers 202.

The coating process of FIG. 7 starts at step 301. The wafers 202 are consecutively guided through a first dual belt conveyor system 201 into the first backing roll 203 loaded with the adhesive carrier tape 204, step 302. The first backing roll 203 and the second backing roll 216 drive the carrier tape 204 from an unwinder (not shown in FIG. 2a) towards the slot-die head 100, step 303. Each wafer 202 is sealed to the adhesive carrier tape 204 when contacting the carrier tape 204, step 304. The sealed wafers 202 are now driven towards to the slot-die head 100 by the advancing carrier tape 204, step 305. When the wafers 202 pass the discharge slot 111b of the slot-die head 100, the alignment support 209 in the form of a vacuum chuck ensures maximum flatness or alignment by a laminar flow of negative pressure, while the wafers 202 are coated with the wet film layer 208, step 306. After passing the discharge slot 111b, the wafers 202 now coated with the film layer 208 reach the light radiation source 210, where the adhesive carrier tape 204 with the wafers 202 is exposed to light in order to loosen the wafers 202 from the carrier tape 204, step 307. The coated wafers 202, 208 then reach the separation platform 215 with a peeling angle 214 greater than 90 degrees, where the movement direction of the carrier tape 204 is changed to separate the wafers 202 from the carrier tape 204, step 308. The separated wafers 202 with the coated film layer 208 are now received by the second transport conveyor belt or exit conveyor belt 219 for removing the coated wafers 202, step 309. Process ends, step 310.

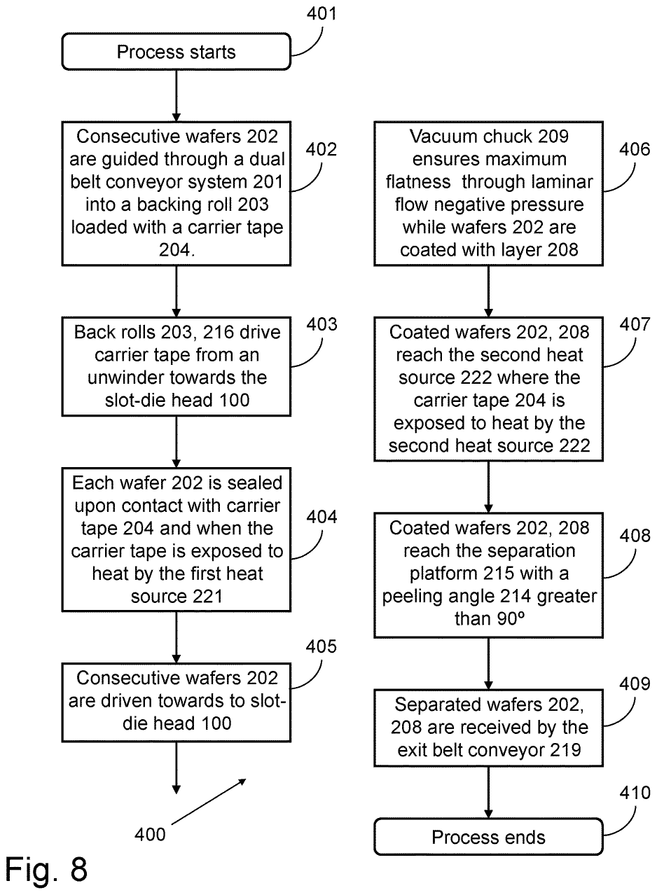

FIG. 8 is a flow-chart illustrating steps of a roll-to-substrate slot-die coating process performed by use of the system 200b of FIG. 2b and using a heat-sensitive adhesive carrier tape 204 and substrates in the form of silicon wafers 202.

The coating process of FIG. 8 starts at step 401. The wafers 202 are consecutively guided through a first dual belt conveyor system 201 into the first backing roll 203 loaded with the adhesive carrier tape 204, step 402. The first backing roll 203 and the second backing roll 216 drive the carrier tape 204 from an unwinder (not shown in FIG. 2a) towards the slot-die head 100, step 403. Each wafer 202 is sealed to the adhesive carrier tape 204 when contacting the carrier tape 204 and when the carrier tape 204 is exposed to heat by the first heat source 221, step 404. The sealed wafers 202 are now driven towards the slot-die head 100 by the advancing carrier tape 204, step 405. When the wafers 202 pass the discharge slot 111b of the slot-die head 100, the alignment support 209 in the form of a vacuum chuck ensures maximum flatness or alignment by a laminar flow of negative pressure while wafers 202 are coated with the wet film layer 208, step 406. After passing the discharge slot 111b, the wafers 202 now coated with the film layer 208 reach the second heat source 222, where the carrier tape 204 is heated to soften the adhesive layer of the carrier tape 204 and loosen the wafers 202 from the carrier tape 204, step 407. The coated wafers 202, 208 then reach the separation platform 215 with a peeling angle 214 greater than 90 degrees, where the movement direction of the carrier tape 204 is changed to separate the wafers 202 from the carrier tape 204, step 408. The separated wafers 202 with the coated film layer 208 are now received by the second transport conveyor belt or exit conveyor belt 219 for removing the coated wafers 202, step 409. Process ends, step 410.

Details for example embodiments of slot-die coating processes following the steps of FIG. 7 using a light-curable adhesive carrier tape 204 and using the system 200a of FIG. 2a, or following the steps of FIG. 8 using a heat-sensitive adhesive carrier tape 204 and using the system 200b of FIG. 2b:
Substrates: The substrates 202 are silicon M6 wafers (ca. 166 mm square) and 180 microns in thickness. The single wafers are aligned on the carrier tape 204 at a distance of about 10 mm from each other.
Carrier tape roll-to-roll system: The first backing roll 203 and the second backing roll 216 shown in FIGS. 2a and 2b are part of a carrier tape roll-to-roll system for driving the carrier tape 204 pass the slot-die coater 100. The remaining components of the carrier tape roll-to-roll system are not shown in FIG. 2a or 2b, but they are all typical components of a roll-to-roll coater system, and may include idle rollers, anti-static units, tension systems, web guides, height adjustable roller units and nip breakers.
Carrier tape when using a light-curable adhesive carrier tape, FIG. 7: The carrier tape 204 has a polyolefin base web layer 224 with and light or UV-sensitive acrylic-based adhesive top layer 223 with a thickness in the range of 10-20 microns. The carrier tape 204 has a width of about 200 mm. The carrier tape 204 is advanced in the machine direction 212 at a web speed of 20 cm/min.
Carrier tape when using a heat-sensitive adhesive carrier tape, FIG. 8: The carrier tape 204 has a polyolefin base web layer 224 with and heat-sensitive acrylic-based adhesive top layer 223 with a thickness in the range of 10-20 microns. The carrier tape 204 has a width of about 200 mm. The carrier tape 204 is advanced in the machine direction 212 at a web speed of 20 cm/min.
Fluid for coating: The fluid being supplied to the slot-die head manifold ink reservoir 111a for being discharged or coated on top of the wafers is a perovskite solution.
Perovskite solution for slot-die coating (1 mL): Scale 1 mmol of Formamidinium Iodide, FAI, (171.97 mg), 1 mmol of Lead Iodide, Pb12, (461.01 mg), 0.1 mmol of Methylammonium Chloride, MACl, (6.75 mg) powders into a vial and mix with 0.46 mL of Acetonitrile, ACN, 0.46 mL of 2-Mercaptoethanol, 2-ME, 0.08 mL of N-Methyl-2-pyrrolidone, NMP. The solution is stirred at room temperature.
Slot-die coating of the perovskite layer: The perovskite solution or ink is fed into a large reservoir connected to a continuous flow peristaltic or diaphragm pumping system (not shown). The pump system allows for continuous or intermittent flow into the slot-die head 100. The coating speed is 20 cm/min, and the pump rate is 100 μL/min, while the distance 109 between the bottom side of the meniscus guide 102 and the front surface of the wafers 202 is 200 μm. The distance 225 between the meniscus guide's bottom side and the carrier tape's top side is 380 μm. The discharge slot has an extension of 18 cm centred with respect to the carrier tape 204 and the sealed wafers 202.
Slot-die coating system: The slot-die coating system comprises a) a alignment support 209 in the form of a platform vacuum chuck with a flat metallic microporous insert 209b allowing to convey a laminar flow of negative pressure, b) a motorized high-precision gantry motion system (not shown) driven by an AC or DC servomotor (not shown) capable of 1-micron resolution steps. This motion system holds a platform (not shown) where the slot-die head 100 is fixed and can be driven upwards and downwards to the desired distance from the substrate 202 or the carrier tape 204.
The alignment support 209 in the form of the platform vacuum chuck with the microporous insert 209b enables the laminar distribution of variable negative pressure (between 2 and 6 bars) to warrant maximum flatness of the carrier tape 204 and substrate 202 during coating.
Light radiation curing when using a light-curable adhesive carrier tape, FIG. 7: After coating, the wafer plates 202, sealed to the top adhesive surface 223 of the carrier tape 204, advance toward the light radiation curing source 210. The illumination area covers the width of the carrier tape 204 transversally, and the illumination intensity impinges the bottom side of the carrier tape 204 delivering between 100 and 400 mW/cm2 in an isoenergetic manner. The light radiation source 210 may have a light spectrum in the range of 390 to 400 nm.
Protective light trap structure 211 on top of light radiation source 210 when using a light-curable adhesive carrier tape, FIG. 7: A highly light absorbing texturized structure 211 may cover the light-exposed area from the top of the moving wafers 202 to prevent stray light radiation from harming the wet film 208 or any functional layers of the wafers 202.
Heat sources 221, 222 for wafer-to-tape bonding and wafer-from-tape separation when using a heat-sensitive adhesive carrier tape, FIG. 8: The first and second heat sources 221 and 222 consist of a platform with variable temperature control to warrantee the adhesive material is heated to 40-50 degrees. While the carrier tape 204 travels across the first and second heat sources, the bottom of the carrier tape may be in direct contact with the heat sources 221, 222 for an effective heat transfer.
Separation platform 215 and peeling angle 214: The adhesive reduction factor after illumination exposure, FIG. 7, or heat exposure, FIG. 8, is proportional to the contact angle or peeling angle 214 on which the carrier tape 204 is pulled away from the flat wafer 202. The platform for separation 215 can be made to provide a variable peeling angle 214 to warrant wafer-from-tape separation at the specific carrier tape or web speed.

The hardware structure required to deliver adequate motion resolution of the slot-die head 100 component to reach the distance 225 between the carrier tape 204 and the bottom side of the meniscus guide 102 can be obtained by the AlphaSC system delivered by FOM Technologies A/S. This slot-die coating system comprises a platform chuck 209 with a flat metallic microporous insert 209b allowing it to convey laminar flow negative pressure and a motorized high-precision gantry motion system driven by an AC or DC servomotor capable of 1-micron resolution steps. This slot-die coating system holds a platform where the slot-die head 100 can be driven upwards and downwards to the desired distance from the substrate or wafer 202 or from the tape 204. Depending on the number of wafers 202 coated simultaneously, the size of the slot-die head 100 can be the size of the FOM low viscosity XL slot-die head, capable of coating widths of up to 20 cm. The FOM XL slot-die head can be delivered by FOM Technologies A/S.

Regarding the light illumination source 210 used for deactivating the adhesive strength on the carrier tape 204 and facilitating wafer-from-tape separation, the light intensity should be strong enough to reach the light radiation dosage and intensity at the carrier tape traveling time. For instance, for a carrier tape 204 with an adhesive that requires 200 mJ/cm2 for the adhesive strength reduction to occur and a coating speed of 15 mm/sec, an illumination source with a spectrum between 390 to 400 nm providing 200 mW/cm2 may be used and should be at least 15 mm long and have a width equivalent or slightly larger than the width of the carrier tape 204 for an effective wafer-to-tape separation to occur. Customized adhesive tape architecture and composition might be required for different types of wafer plates with different sizes, bottom topography, and chemistry. Henceforth, different illumination conditions might be required. The same is the case when varying the coating velocity. A series of 2-4 illumination sources with modulable intensity should provide adequate functionality in a wide variety of processing scenarios.

The invention has been described in conjunction with various embodiments herein. However, other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality.

1. A method for applying a fluid discharged from a slot-die head to one or more substrates, said slot-die head holding a discharge slot and a meniscus guide with a bottom part of the meniscus guide extending below the discharge slot, and said substrate(s) having a front surface, a back surface, edge surfaces between the front and back surfaces, a maximum width, a maximum length, and a thickness; wherein the method comprises:
a) providing an adhesive carrier tape having an adhesive front surface and a non-adhesive back surface;
b) positioning the one or more substrates on the front surface of the carrier tape;
c) providing a substantially sealed connection between the back surface of the one or more substrates and the front surface of the carrier tape;
d) positioning the carrier tape holding the one or more substrates adjacent the slot-die head to define a predetermined distance between the front surface of the carrier tape and a bottom edge of the bottom part of the meniscus guide; and
e) advancing the carrier tape with the one or more substrates in a machine direction past the discharge slot of the slot-die head while discharging the fluid from the discharge slot as a wet film layer on the front surface of the one or more substrates.

2. A method, according to claim 1, wherein the distance between the carrier tape's front surface and the meniscus guide's bottom edge is larger than the thickness of the substrate(s).

3. A method according to claim 1, wherein the discharging of fluid from the discharge slot to the one or more substrates in step e) is performed so as to cover the whole front surface of the substrate(s) and so as to cover the edge surfaces of the substrate(s).

4. A method according to claim 1, wherein several separate substrates are consecutively positioned on the front surface of the adhesive carrier tape with a distance between each substrate, and
wherein the carrier tape with the substrates is continuously advanced in the machine direction for a time period which allows discharging of the fluid from the discharge slot as a wet film layer on the front surface of several of the consecutively positioned substrates.

5. A method according to claim 1, wherein an alignment support is provided for supporting the back surface of the carrier tape during at least part of step e) to maintain said predetermined distance between the front surface of the carrier tape and the bottom edge of the meniscus guide when discharging the fluid from the discharge slot onto the substrate(s).

6. A method according to claim 5, wherein said alignment support is a vacuum chuck, said vacuum chuck providing a negative pressure between the vacuum chuck and the carrier tape to planarize the substrate(s) sealed to the carrier tape during discharging of the fluid from the discharge slot onto the substrate(s).

7. A method according to claim 1, wherein the method further comprises a step of deactivating the sealed connection between the one or more substrates and the adhesive carrier tape.

8. A method according to any one of the claim 1, wherein the adhesive carrier tape is a light-curable tape, and wherein light from a light radiation source is radiated into the back surface of the carrier tape below the substrate(s) positioned on the front surface of the carrier tape after the substrate(s) has fully passed the discharge slot thereby inhibiting or deactivating the connection between the one or more substrates and the adhesive carrier tape.

9. A method according to claim 1, wherein the adhesive carrier tape is a heat-sensitive tape, and step c) of providing a sealed connection between the back surface of the substrate(s) and the front surface of the carrier tape includes a heating process by use of a first heat source in which heat is supplied to the back surface of the carrier tape below the substrate(s) positioned on the front surface of the carrier tape, and
wherein heat is supplied by a second heat source to the back surface of the carrier tape below the substrate(s) positioned on the front surface of the carrier tape after the substrate(s) has fully passed the discharge slot, thereby deactivating the sealed connection between the one or more substrates and the adhesive carrier tape.

10. A method according to any claim 7, wherein the method further comprises a step of separating the one or more substrates from the adhesive carrier tape, and wherein the step of deactivating the sealed connection between the one or more substrates and the adhesive carrier tape is followed by the step of separating the substrate(s) from the adhesive carrier tape.

11. A method according to claim 10, wherein a substrate-tape separation platform and a second backing roll are provided and arranged for separating the substrate(s) from the adhesive carrier tape and wherein the substrate-tape separation platform and the second backing roll are arranged for changing the direction of the adhesive carrier tape by a peeling angle of at least 90 degrees with reference to the machine direction.

12. A system for applying a fluid to one or more moving substrates, said substrate(s) having a front surface, a back surface, edge surfaces between the front and back surfaces, a maximum width, a maximum length, and a thickness; wherein the system comprises:
a slot-die head holding a discharge slot and a meniscus guide with a bottom part of the meniscus guide extending below the discharge slot;
an adhesive substrate carrier tape having an adhesive front surface and a non-adhesive back surface, said carrier tape holding the one or more substrates on its front surface, and said carrier tape being configured for providing a substantially sealed connection between the back surface of the one or more substrates and the front surface of the carrier tape;
a roll system for advancing the carrier tape holding the one or more substrates in a machine direction past the discharge slot of the slot-die head; and
an alignment support for supporting the back surface of the carrier tape to maintain a predetermined distance between the front surface of the carrier tape and a bottom edge of the meniscus guide and thereby to maintain a distance between the front surface of the substrate(s) and the bottom edge of the meniscus guide when advancing the carrier tape holding the one or more substrates in a machine direction past the discharge slot of the slot-die head.

13. A system according to claim 12, wherein the distance between the carrier tape's front surface and the meniscus guide's bottom edge is larger than the substrate's(s) thickness.

14. A system according to claim 12, wherein the discharge slot extends along the width of the substrate(s) and has an extension larger than the maximum width of the substrate(s), wherein the slot-die head is configured for discharging the fluid from the discharge slot as a wet film layer on the front surface of the one or more substrates when the carrier tape holding the one or more substrates is advanced in the machine direction past the discharge slot of the slot-die head, and
wherein the slot-die head is configured for discharging the fluid from the discharge slot to the one or more substrates so as to cover the whole front surface of the substrate(s) and so as to cover the edge surfaces of the substrate(s).

15. A system according to claim 12, wherein several separate substrates are consecutively positioned on the front surface of the adhesive carrier tape with a distance between each substrate, and
wherein the roll system is configured for continuously advancing the carrier tape with the substrates in the machine direction for a time period which allows discharging of the fluid from the discharge slot as a wet film layer on the front surface of several of the consecutively positioned substrates.

16. A system according to claim 12, wherein said alignment support is a vacuum chuck, said vacuum chuck configured for providing a negative pressure between the vacuum chuck and the carrier tape to planarize the substrate(s) sealed to the carrier tape when passing the discharge slot.

17. A system according to claim 12, wherein the system further comprises a deactivating system for deactivating the sealed connection between the one or more substrates and the adhesive carrier tape.

18. A system according to claim 12, wherein the adhesive carrier tape is a light-curable tape, and wherein the deactivating system holds a light radiation source arranged for supplying light to the back surface of the carrier tape below the substrate(s) positioned on the front surface of the carrier tape, and
wherein the light radiation source is arranged downstream of the slot-die head and the alignment support with reference to the machine direction.

19. A system according to claim 12, wherein the adhesive carrier tape is a heat-sensitive tape, and wherein the system further comprises a first heat source for supply of heat to the back surface of the carrier tape below the substrate(s) positioned on the front surface of the carrier tape, and
wherein the first heat source is arranged upstream of the slot-die head and the alignment support with reference to the machine direction.

20. A system according to claim 19, wherein the system further comprises a deactivating system for deactivating the sealed connection between the one or more substrates and the adhesive carrier tape,
wherein the deactivating system comprises a second heat source arranged for supply of heat to the back surface of the carrier tape below the substrate(s) positioned on the front surface of the carrier tape, and
wherein the second heat source is arranged downstream of the slot-die head and the alignment support with reference to the machine direction.

21. A system according to claim 12, wherein the system further comprises a separating system for separating the one or more substrates from the adhesive carrier tape,
wherein the separating system comprises a substrate-tape separation platform and a second backing roll, and
wherein the substrate-tape separation platform and the second backing roll are arranged for changing the direction of the adhesive carrier tape by a peeling angle of at least 90 degrees with reference to the machine direction.
